(19) United States
(12) Patent Application Publication
(10) Pub. No.: US 2011/0108312 A1
(43) Pub. Date: May 12, 2011

(54) Shock damping system for a surface mounted vibration sensitive device

(75) Inventors: Karoly Becze, Calgary (CA); Pee-Jay Lanneville, Airdrie (CA)

(73) Assignee: NovAtel Inc., Calgary (CA)

(21) Appl. No.: 12/943,564

(22) Filed: Nov. 10, 2010

Related U.S. Application Data
(60) Provisional application No. 61/260,591, filed on Nov. 12, 2009.

(51) Int. Cl. H05K 1/00; H05K 3/30

(52) U.S. Cl. 174/258; 29/832

(57) ABSTRACT

The inventive shock damping system for vibration sensitive surface mounted devices consists of an elastomeric material having conductive fiber material disposed between a printed circuit board (PCB) and a surface mounted device. Once disposed between PCB and surface mounted device, the elastomeric material, the PCB and the surface mounted device are compressed together with a component restraining system, to provide a secure electrical connection between one or more interconnect pads conductively attached to surface mounted device and the PCB. The elastomeric material allows signals and current to flow between surface mounted device and PCB without the use of any attached wires or leads while at the same time providing a system for damping any shocks or vibrations that may be transferred to surface mounted device through the PCB or through the protective component restraining system that encloses the device and the elastomeric material.

### CROSS-REFERENCE TO RELATED APPLICATIONS

The present application claims the benefit of U.S. Provisional Patent Application Ser. No. 61/260,591, which was filed on Nov. 12, 2009, by Karoly Becze et al. for a A SHOCK DAMPING SYSTEM FOR A SURFACE MOUNTED VIBRATION SENSITIVE DEVICE and is hereby incorporated by reference.

### BACKGROUND OF THE INVENTION

1. Field of the Invention

This invention relates generally to shock and/or vibration-damping apparatus for providing a shock damping system to a surface mounted vibration sensitive device, such as, a surface mounted temperature controlled crystal oscillator to be disposed in rugged/high shock/vibration environments.

2. Background Information

A surface mounted temperature controlled crystal oscillator (SMT-TCXO) is an electronic circuit that uses the mechanical resonance of a vibrating crystal of piezoelectric material to create an electrical signal with a very precise frequencies over a wide ranges of ambient temperatures. This frequency source is commonly used to provide a stable clock signal for digital integrated circuits, and to stabilize frequencies for radio transmitters and receivers and the like. One of the most common types of piezoelectric resonator is a quartz crystal. Because they can be used over wide temperature ranges, SMT-TCXOs are ideal for applications that have demanding timing specifications, such as GNSS applications for use in surveying and so forth.

These applications may require the use of SMT-TCXO based GNSS receivers in environments in which there is a risk of high impact to the SMT-TCXO. For example, during normal usage of a survey pole apparatus, a GNSS receiver may receive shock while placing a GNSS equipped survey pole at an intended survey point. The crystals are mechanical resonators. Hence, they may exhibit a sudden phase shift adversely affecting performance of the GNSS receiver or other host circuits. In addition to the extreme sensitivity of the crystals, the SMT-TCXO itself is very small, on the order of 10 mm. Thus, finding a system which provides sufficient damping properties while at the same time providing a continuous electrical contact has proven to be difficult at best.

In previous designs, vibration/shock isolators such as rubber washers or spacers have been disposed between a housing and a printed circuit board (PCB) which the SMT-TCXO is directly mounted via a soldering processes, in order to absorb some of the vibration/shock related to the use of the device. However, in this system, the whole PCB is isolated which lends itself capable of minor relative motion with respect to the housing during vibration/shock events. Thus is, not ideal because the PCB and the SMT-TCXO are in direct contact with each other. It is also difficult to control heat transfer from the PCB to the SMT-TCXO when they are in direct contact with each other. As known to those skilled in the art, heat can adversely affect the performance of the crystal, in ways that cannot be readily determined, and thus, compensated for, based on changes in ambient temperature. This phenomena increases as the SMT-TCXO mounted PCB generates excessive heat.

The GNSS receiver tracking loops are extremely sensitive to oscillator phase changes. Therefore, there remains a need for a shock damping system which would both absorb any shock that may be transferred to the device and at the same time protect the SMT-TCXO from heat transfer from the PCB.

### SUMMARY OF THE INVENTION

The current invention overcomes the disadvantages of the prior art by providing a shock damping and thermal isolation system for a surface mounted temperature controlled crystal oscillator (SMT-TCXO) disposed in a rugged, high shock/vibration environment while providing stable electrical connection. Specifically, an elastomeric material having a relative z-axis conductive fiber material incorporated within, may be disposed between a printed circuit board (PCB) or other electrically interconnecting mounting substrate and a SMT-TCXO. The elastomeric material is sized and positioned across the entire bottom surface of the SMT-TCXO to completely protect the SMT-TCXO from direct contact with the PCB. Once the elastomeric material is disposed between the PCB and the SMT-TCXO, the components are compressed together with a component restraining system. The component restraining system facilitates a secure electrical connection between one or more interconnect pads attached to the SMT-TCXO device and one side of the elastomeric material, and one or more interconnect pads attached to the PCB and an opposite side of the elastomeric material, while at the same time providing protection to the SMT-TCXO from vibrations that would otherwise be transferred to the SMT-TCXO. The elastomeric material then allows signals and current to flow between the SMT-TCXO and the PCB via the z-axis conductive fibers, eliminating the need for attached wires or leads, such that mounting the SMT-TCXO is less complex.

The component restraining system secures the elastomeric material and SMT-TCXO assembly to the PCB by applying a required amount of pressure to a top side of the SMT-TCXO opposite the PCB from the top side of a properly sized inner cavity of the component restraining. The pressure provided from the top side of the inner cavity opposite the SMT-TCXO ensures a continuous electrical contact between the one or more interconnect pads of the SMT-TCXO and the one or more interconnect pads of the PCB through the elastomeric material. Alternative embodiments of the present invention may also dispose an additional or second elastomeric material between the component restraining system and the SMT-TCXO to provide additional damping for the SMT-TCXO and prevent damage and vibration/shock transfer to the SMT-TCXO from the restraining system. The additional elastomeric material, however, does not necessarily provide electrical connections to the SMT-TCXO, and thus, this material may, but need not include conductive fibers.

By rigidly mounting (i.e. providing no relative motion) the PCB 120 and isolating the SMT-TCXO 110, an optimal heat transfer path can be achieved as the main method of dissipating the generated heat via conduction through the PCB 120 and directly into the housing 105.

The same shock damping system may be used with other surface mounted devices for the same reasons and/or to provide damping of high frequency vibrations that would otherwise adversely affect the performance of the device.

### BRIEF DESCRIPTION OF THE DRAWINGS

The invention description below refers to the accompanying drawings, of which:

FIG. 1 is an illustrative embodiment of the shock damping system for an SMT-TCXO device;

FIG. 2 is an illustrative embodiment of an exemplary elastomeric material which may be advantageously used with the present invention;

FIG. 3 is an illustrative embodiment of an exemplary elastomeric material which may be advantageously used with the present invention;

FIG. 4 is an illustrative embodiment of an alternative housing for the shock damping system for the SMT-TCXO device;

### DETAILED DESCRIPTION OF AN ILLUSTRATIVE EMBODIMENT

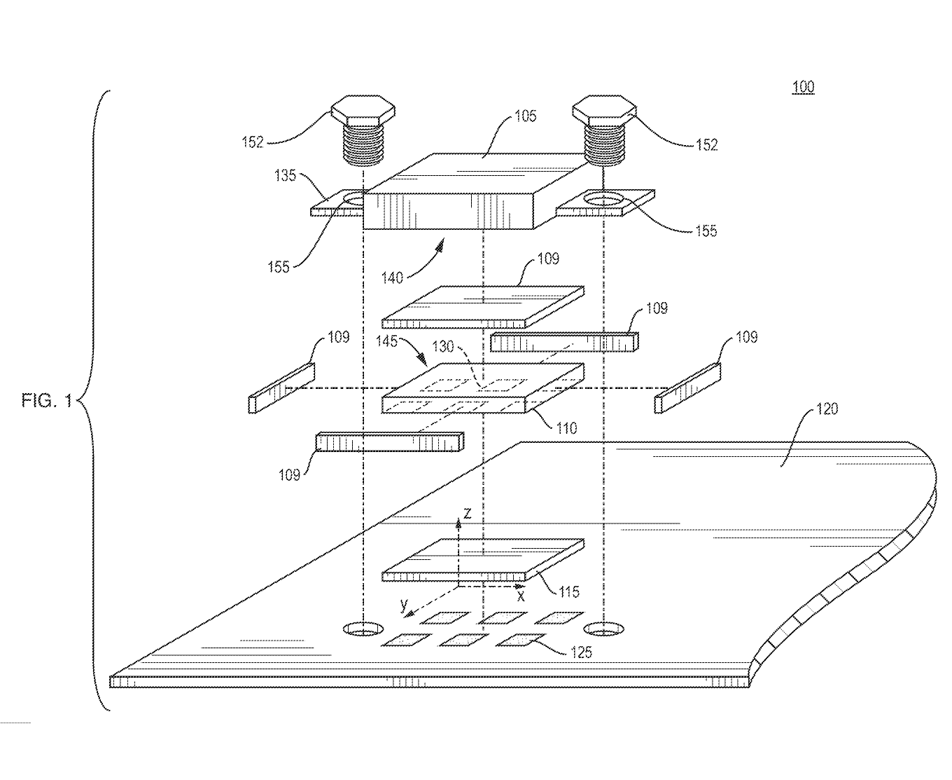

FIG. 1 is an illustrative embodiment of the shock damping system for vibration sensitive surface mounted devices, for example, a surface mounted temperature controlled crystal oscillator (SMT-TCXO). Specifically, an elastomeric material 115 having relative z-axis conductive regions, here, conductive fibers, separated by non-conductive regions, may be disposed between a printed circuit board (PCB) 120 or other electrically interconnecting mounting substrate and an SMT-TCXO device 110. The elastomeric material 115 is sized and positioned across the entire bottom surface of the SMT-TCXO 110 to completely protect the SMT-TCXO 110 from physical contact with the PCB 120 and otherwise damp larger vibrations of the SMT-TCXO that may be caused by, for example, impact. Once disposed between PCB 120 and SMT-TCXO 110, all components are compressed together with a component restraining system 105, to maintain alignment between component connect points 110 and PCB connect points 125 and provide a secure electrical connection between one or more interconnect pads 130 conductively attached to SMT-TCXO 110 and one or more interconnect/landing pads 125 conductively attached to PCB 120. The elastomeric material 115 allows signals and current to flow between SMT-TCXO 110 and PCB 120 without the use of any attached wires or leads while at the same time providing a system for damping any shocks or vibrations that may be transferred through the PCB to SMT-TCXO 110. In addition, component mounting is simplified because the elastomeric material is only z-axis conductive, and thus, component pad alignment constraints are eased.

As mentioned above, a component restraining system 105 is employed to apply a specific amount of pressure to the top side 145 of SMT-TCXO 110 that is opposite the PCB 120, such that when affixed to the PCB 120 a required compression of the elastomeric material 115 is achieved to provide continuous electrical contact through the elastomeric material. This required compression is vendor specific and depends on the type of elastomeric material which is being used. In order to provide the required compression to the elastomeric material between the SMT-TCXO 110 and the PCB 120, an inner cavity (not shown) of the component restraining system 105 is sized essentially to surround the SMT-TCXO 110 and the elastomeric material when the elastomeric material is in the desired compressed state. The component restraining system is affixed to the PCB 120 using screws 152, and the pressure exerted from the top side of the inner cavity opposite the SMT-TCXO 110 as the bolts are tightened essentially clamps the elastomeric material 115 between the SMT-TCXO 110 and the PCB 120 thereby provides the compression required to the elastomeric material 115 to ensure a continuous electrical contact through the elastomeric material between the one or more interconnect pads on the SMT-TCXO and the one or more interconnect pads on the PCB.

Specifically, in the present invention, the proper size of the inner cavity is directly related to the size of the SMT-TCXO, and in particular the thickness of the SMT-TCXO. The cavity is sized such that when the component restraining system is in place and affixed to the PCB 120, the top side of the inner cavity (not shown), which is opposite the SMT-TCXO, holds the SMT-TCXO to clamp the elastomeric material to the desired compressed state. In one embodiment of the present invention, a thickness or height of the inner cavity is illustratively determined by applying the formula:

H_{cavity}=H_{TCXO}+H_{comp}

In the illustrative formula, H_{TCXO} is the thickness of the SMT-TCXO 110, and H_{comp} is the thickness of the elastomeric material in the desired compressed state. The height of the elastomeric material at a desired compression is equal to Hₙₒₘ(1-D), where Hₙₒₘ is the nominal height of the elastomeric material 115 and D is the percent deflection of elastomeric material, e.g., usually around 10-25% depending on the type of elastomeric material being used. Provided the inner cavity height is sized according to the above calculation, the compression restraining system, when affixed to the PCB 120, will provide alignment and the required amount of compression for a continuous electrical contact between the one or more interconnect pads on the SMT-TCXO and the one or more interconnect pads on the PCB

In alternative embodiments of the present invention, additional elastomeric material 109 may also be disposed between component restraining system 105 and SMT-TCXO 110 and/or on each of the sides of the SMT-TCXO along the x-axis and the y-axis. The optionally added elastomeric material does not necessarily provide any conductive purpose to the overall device, and may, but need not, contain conductive fibers. The inclusion of the optional material provides additional damping and alignment to SMT-TCXO 110, thereby allowing even further protection to the device against, for example, vibrations transferred through the component restraining system 105. In this embodiment of the present invention, the height of the inner cavity is illustratively determined by applying the formula:

H_{cavity}=H_{TCXO}+H_{nom conn}(1−D₁)+H_{nom layer}(1−D₂)

In the above illustrative formula, H_{nom conn} is the nominal height of the conductive elastomeric layer 115 and H_{nom layer} is the nominal height of the non-conductive layer 109. Furthermore, D₁ is the percent deflection of the conductive elastomeric material 115, while D₂ is the percent deflection of the additional material 109. Although additional material 109 may be the same elastomeric material as 115, it may also be any other material that has the same absorption properties. This material, however, need not have the same hardness, thickness or conductive properties as the conductive elastomeric material 115.

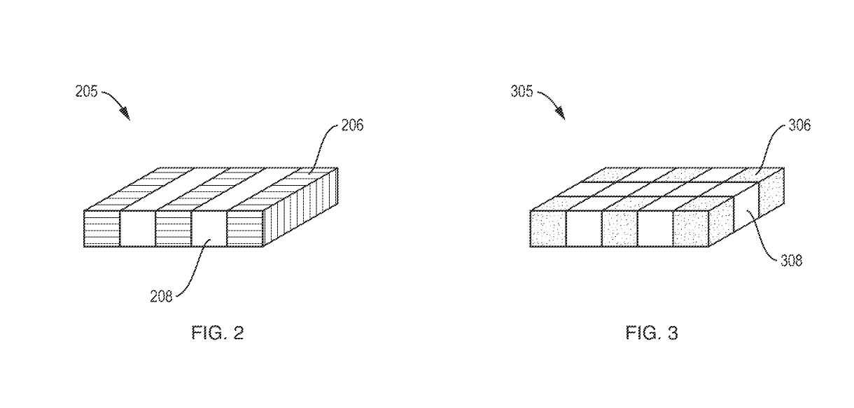

Illustratively, two or more screws are threaded through two or more apertures 155 in housing 105 and into corresponding apertures 155 in PCB 120, to secure the housing in place while at the same time compressing the elastomeric material. In alternative embodiments, however, adhesive or any other securing apparatus, such as direct solder, may be used to attach component restraining system 105 to PCB 120. Furthermore, although the above invention describes elastomeric material 105 as being a z-axis fiber conductive material, other variations of elastomeric materials may also be used. FIGS. 2-3 illustrate exemplary alternative embodiment of the elastomeric material 105 which may be advantageously used with the present invention. Specifically, FIGS. 2 and 3 alternatively illustrate utilizing an exemplary combination elastomeric material that has selective portions 206, 306 of the material that are conductive and other portions 208, 308 of the material that are non-conductive.

Elastomeric material 205 illustrates a type of material that may be advantageously used in place of elastomeric material 105 in the system of FIG. 1. Material 205 is manufactured with alternating conductive and non-conductive stripes known by those skilled in the art as “Zebra Stripes.” While assembling the system, the material 205 is positioned so that one or more of the stripes 206 that are conductive are aligned with interconnect pads 130 and 125. As discussed above, the alignment of the conductive stripes and pads need not be precise, since the conductive stripes are disposed between non-conducting stripes 208.

Alternatively, combination material 305 of FIG. 3 is selectively molded to match the arrangement of the interconnecting pads 125 and 130, such that conductive material 306 extends between the pads and non-conductive material 308 surrounds the conductive material.

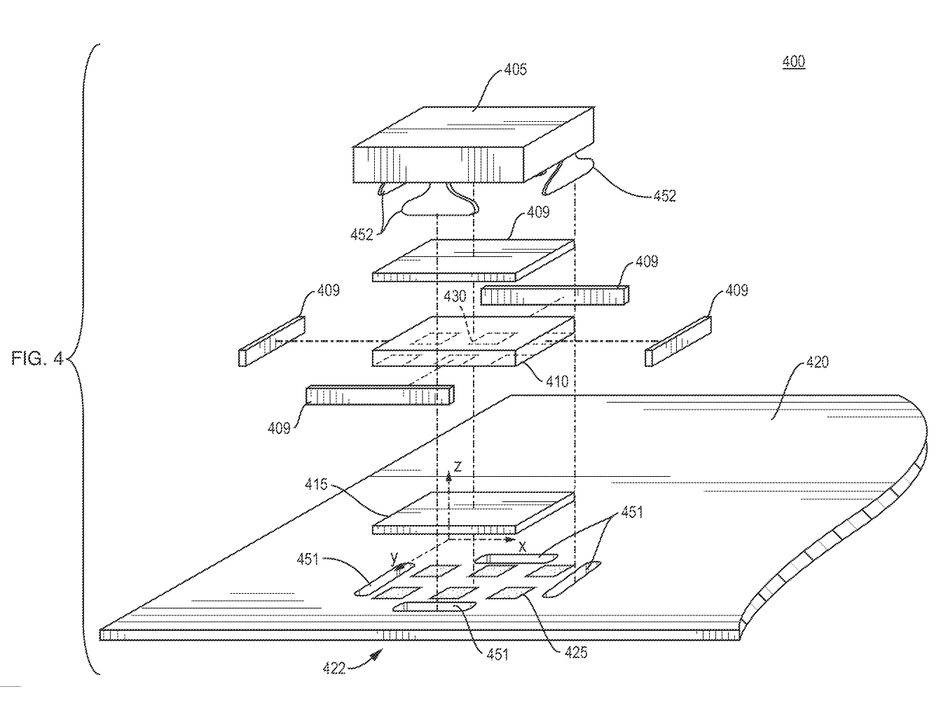

Although the above described illustrative embodiment utilizes attached mounting bracket and screws to secure the component restraining system 105 to the PCB 120, alternative embodiments, may utilize, adhesive or any other securing apparatus, such as direct solder, to attach component restraining system 105 to PCB 120. For example, FIG. 4 illustrates an alternative embodiment of the present invention where the screws 152 and the apertures 155 have been replaced with twist tabs 452. Shock damping system 400 utilizes the twist tabs 452 which slide into slots 451 in the PCB 420 and are then tightly twisted 90 degrees over the edges of the slots 451 on a side opposite 422 of the SMT TXCO 410 thereby securing the component restraining system 405 in place while at the same time compressing the elastomeric material 409 and/or 410 against interconnecting pads 425 and 430. Beneficially, this embodiment allows users to quickly remove the component restraining system 405, e.g., to replace various components of the above described shock damping system.

Advantageously the current invention absorbs high shocks and vibrations transferred to a SMT-TCXO device while at the same time alleviating concerns with alignment and disruption of signals and electrical current from the SMT-TCXO to an interconnecting substrate or PCB in the event the SMT-TCXO device is subjected to excessive shock and vibration. For example, the above described component restraining system aligns and constrains the elastomeric material so that the material does not move between the SMT-TCXO 110 and the PCB 120 conductive pads 130 and 125 even when the device is impacted by an external force. Therefore, the device provides the user with a rugged impact resistant device that would be ideal in, for example, surveying environments. Furthermore, by rigidly mounting (i.e. providing no relative motion) the PCB 120 and isolating the SMT-TCXO 110, an optimal heat transfer path can be achieved as the main method of dissipating the generated heat via conduction through the PCB 120 and directly into the housing 105.

Illustrative embodiment of the present invention may be implemented in a GNSS receiver mounted on a survey poll that is subjected to shock forces in a single direction. The shock forces originate when the surveyor, carrying the poll, jams the tip of the survey poll into the ground, perhaps hitting a rock or other hard surface. The shock propagates up the length of the poll to the location of the GNSS electronics containing the vibration sensitive components, e.g., the SMT TXCO 110. Illustratively, the PCB 120, elastomeric material 115, the SMT TCXO 110 and component restraining system 105 are placed such that the direction of the shock is through the z axis, and therefore through the elastomeric material 115 to the SMT TCXO 110. In other words, the PCB is mounted horizontally with respect to the vertical axis of the pole. In this configuration, the elastomeric material 105 need only be placed under the SMT TCXO 110 because shock is not expected from any other direction.

In other high vibration environments, such as for example a helicopter, high vibration and shock waves can be expected from all directions. In these environments, the vibration sensitive elements must be protected by compressive shock absorbing material from all sides. Accordingly, the elastomeric material may be placed between the vibration sensitive components, e.g., the SMT TCXO, and the incoming direction of the expected shock waves.

Furthermore, although the present invention has been described as being implemented in a SMT-TCXO, the present invention may also advantageously be applied to any vibration sensitive devices that may be adversely impacted by vibrations, for example, inertial sensors, gyros, accelerometers, and so forth.

The foregoing description has been directed to specific embodiments of this invention. It will be apparent, however, that other variations and modifications may be made to the described embodiments, with the attainment of some or all of their advantages. For instance, it is expressly contemplated that the assemblies, systems, and materials described herein may be implemented in various forms. Furthermore, in alternate embodiments, the optional second elastomeric layer 109 may provide an electrically conductive purpose. Therefore, FIG. 1 is provided as exemplary only and should not be construed to limit the claimed invention in any way. Accordingly, this description is to be taken only by way of example and not to otherwise limit the scope of the invention.

What is claimed is:

1. A shock damping system for a surface mounted device:
one or more interconnect pads attached to the surface mounted device and one or more interconnect pads attached to an electrically interconnecting mounting substrate;
an elastomeric material having a plurality of electrically conductive regions incorporated within to allow electrical current to flow through the material, and non-conductive regions disposed between the conductive regions, the elastomeric material being disposed between the electrically interconnecting mounting substrate and the surface mounted device; and
a component restraining system configured to surround the surface mounted device and the elastomeric material and compress the elastomeric material between the electrically interconnecting mounting substrate and the surface mounted device to provide a secure electrical connection between the one or more interconnect pads attached to the surface mounted device and the electrically interconnecting mounting substrate.

2. The shock damping system of claim 1, wherein the component restraining system secures the elastomeric material and the surface mounted device assembly to the electrically interconnecting mounting substrate by applying a required amount of pressure to a top side of the surface mounted device opposite the electrically interconnecting mounting substrate.

3. The shock damping system of claim 2, wherein the required compression ensures a continuous electrical contact between the one or more interconnect pads of the surface mounted device and the one or more interconnect pads of the electrically interconnecting mounting substrate, the required compression achieved by sizing an inner cavity of the component restraining system so that the height of the inner cavity is equal to the height of the surface mounted device plus a compressed height of the elastomeric material.

4. The shock damping system of claim 1 further including a second elastomeric material disposed between the component restraining system and the surface mounted device.

5. The shock damping system of claim 1, wherein the surface mounted device is a temperature controlled crystal oscillator.

6. The shock damping system of claim 1, wherein the surface mounted device is a vibration sensitive device.

7. The shock damping system of claim 1, wherein the electrically interconnecting mounting substrate is a printed circuit board.

8. The shock damping system of claim 1, wherein compression is provided to the component restraining system by sizing an inner cavity of the component restraining system, surrounding the surface mounted device and the elastomeric material with the inner cavity of the component restraining system and affixing a housing to the printed circuit board using two or more screws, the affixing effectively clamping the surface mounted device to the elastomeric material and the electrically interconnecting mounting substrate.

9. The shock damping system of claim 1, wherein the conductive regions are z-axis conductive fibers and elastomeric material conducts current via z-axis fibers.

10. The shock damping system of claim 1, wherein the conductive regions are portions of the elastomeric material that are conductive stripes and the elastomeric material conducts current via the conductive portions.

11. The shock damping system of claim 10, wherein the elastomeric material is includes alternating conductive and non-conductive stripes.

12. The shock damping system of claim 11, wherein before the component restraining system is in place, the elastomeric material is positioned so that the stripes that are conductive are aligned with the one or more interconnect pads on the surface mounted device and the one or more interconnect pads on the electrically interconnecting mounting substrate.

13. The shock damping system of claim 10, wherein the conductive portions of the elastomeric material are selectively arranged to correspond to the interconnect pads on the PCB and surface mounted device respectively so that the conductive portions are in a same location as the one or more interconnecting pads of both the surface mounted device and the electrically interconnecting mounting substrate.

14. A method comprising:
positioning an elastomeric material between a surface mounted device and an electrically interconnecting mounting substrate, the elastomeric material having a plurality of electrically conductive regions incorporated within the elastomeric material wherein the surface mounted device and the printed circuit board each are attached to one or more interconnect pads;
compressing, using a component restraining system, the electrically interconnecting mounting substrate, the elastomeric material and the surface mounted device together to facilitate a secure electrical connection between the one or more interconnect pads attached to the printed the surface mounted device and the electrically interconnecting mounting substrate; and
conducting current and signals between the surface mounted device and the electrically interconnecting mounting substrate through the elastomeric material.

15. The method of claim 14, wherein compressing further comprises applying a required amount of pressure to a top side of the surface mounted device opposite the electrically interconnecting mounting substrate.

16. The method of claim 15, wherein the required compression ensures a continuous contact between the one or more interconnect pads of the surface mounted device and the one or more interconnect pads of the electrically interconnecting mounting substrate, the required compression determined by correctly sizing the restraining system cavity to the needed compression of the elastomeric material.

17. The method of claim 14, further comprising disposing additional elastomeric material between the component restraining system and the surface mounted device, the additional elastomeric material being electrically conductive.

18. The method of claim 14, wherein compressing further comprises bolting affixing a housing to the printed circuit board using two or more twist tabs, the affixing clamping the surface mounted device to the elastomeric material and the electrically interconnecting mounting substrate.

19. The method of claim 14, wherein conducting further comprises conducting the current and signals through the elastomeric material via z-axis fibers in the elastomeric material.

20. The method claim 14, wherein the elastomeric material is includes alternating conductive and non-conductive stripes, the conductive stripes aligned with the one or more interconnect pads on the surface mounted device and the one or more interconnect pads on the electrically interconnecting mounting substrate.
